(19) United States
(12) Patent Application Publication
(10) Pub. No.: US 2026/0185868 A1
(43) Pub. Date: Jul. 2, 2026

(54) SUBSTRATE PROCESS SYSTEM AND METHOD FOR DETERMINING ABNORMALITY OCCURRENCE THROUGH DRIVING NOISE ANALYSIS

(71) Applicant: KCTECH CO., LTD., Gyeonggi-do (KR)

(72) Inventor: Moon Gi CHO, Gyeonggi-do (KR)

(73) Assignee: KCTECH CO., LTD., Gyeonggi-do (KR)

(21) Appl. No.: 19/435,742

(22) Filed: Dec. 30, 2025

(30) Foreign Application Priority Data
Jan. 2, 2025 (KR) 10-2025-0000182

(51) Int. Cl. G01H 3/08; G01H 3/06

(52) U.S. Cl. CPC G01H 3/08; G01H 3/06

(57) ABSTRACT

A substrate process system includes a process device configured to perform a process on a substrate, a sensor configured to detect driving noise generated from the process device, and a processor configured to analyze the driving noise detected by the sensor and determine an abnormality occurrence in the process device.

### CROSS-REFERENCE TO RELATED APPLICATION

This application claims the benefit of Korean Patent Application No. 10-2025-0000182, filed on January 2, 2025, in the Korean Intellectual Property Office, the entire disclosure of which is incorporated herein by reference for all purposes.

### BACKGROUND

### 1. Field of the Invention

One or more embodiments relate to a substrate process system and a method thereof for determining an abnormality occurrence through a driving noise analysis.

### 2. Description of the Related Art

In manufacturing a semiconductor device, a chemical mechanical polishing (CMP) process is needed, which includes polishing, buffing, and cleaning. A semiconductor device has a form of a multi-layer structure, which includes a substrate layer on which a transistor element having a diffusion area is formed. On the substrate layer, a connecting metal line is patterned and electrically connected to a transistor element that forms a functional component. As is well known, a patterned conductive layer is insulated from another conductive layer by an insulating material, such as silicon dioxide. As more metal layers and associated insulating layers are formed, the need for planarizing the insulating material increases. Without planarizing, the manufacturing of additional metal layers becomes substantially more difficult due to large variations in surface morphology. Furthermore, since a metal line pattern is formed of an insulating material, a metal CMP process removes excess metal.

While a process on the substrate is in progress, some members may wear out due to friction. These members are consumable members and require replacing at appropriate times. To improve process efficiency and work convenience, there is a need for technology that can automatically determine the degree of wear and/or timing of replacement of consumable members.

The above description is information the inventor(s) acquired during the course of conceiving the present disclosure, or already possessed at the time, and is not necessarily art publicly known before the present application was filed.

### SUMMARY

Embodiments provide a substrate process system and a method thereof for determining an abnormality occurrence in an automated manner through a driving noise analysis.

According to an aspect, there is provided a substrate process system including a process device configured to perform a process on a substrate, a sensor configured to detect driving noise generated from the process device, and a processor configured to analyze the driving noise detected by the sensor and determine an abnormality occurrence in the process device.

The processor may be configured to determine an abnormality occurrence in the process device using a database storing information regarding driving noise in a normal state and information regarding driving noise in each abnormal state.

The processor may be configured to convert the driving noise into a frequency domain through a Fourier transform and detect a change in a frequency spectrum.

The processor may be configured to convert the driving noise into a time-frequency domain through a Fourier transform for each determined time interval and detect a change in a time-frequency spectrum.

The processor may be configured to convert the driving noise into a time-frequency domain through a wavelet transform and detect a change in a time-frequency spectrum.

The processor may be configured to determine an abnormality occurrence in the process device through Envelope analysis, which tracks a change in an amplitude of a designated target frequency band for the driving noise.

The processor may be configured to learn a pattern of driving noise generated in a normal state and an abnormal state through machine learning and compare and analyze a pattern extracted from the driving noise detected by the sensor with a learned pattern of each state to determine an abnormality occurrence in the process device.

The processor may be configured to calibrate the driving noise detected by the sensor based on a degree of wear of a consumable member.

The processor may be configured to generate a notification when it is determined that an abnormality has occurred in the process device.

The processor may be configured to detect a premonitory pattern from the driving noise detected by the sensor and generate a notification in advance before the process device enters an abnormal state.

The process device may include a substrate polishing device or a substrate cleaning device.

According to an aspect, there is provided a method of determining an abnormality occurrence in a process device using the substrate process system according to claim 1, the method including performing a process on the substrate, detecting driving noise generated from the process device, and analyzing, by the processor, the driving noise detected by the sensor and determining, by the processor, an abnormality occurrence in the process device.

The method may further include generating, by the processor, a notification for a user when it is determined that an abnormality has occurred in the process device.

Additional aspects of embodiments will be set forth in part in the description which follows and, in part, will be apparent from the description, or may be learned by practice of the disclosure.

According to embodiments, an abnormality occurrence in a process device may be determined in an automated manner through a driving noise analysis, and accordingly, process efficiency and work convenience may be improved.

According to embodiments, an abnormality occurrence in a process device may be determined in an automated manner in real time while a process is in progress.

The effects of the substrate process system and the method according to embodiments are not limited to the above-mentioned effects, and other unmentioned effects can be clearly understood from the following description by one of ordinary skill in the art.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a block diagram schematically illustrating a substrate process system according to an embodiment;

FIG. 2 is a plan view of a substrate polishing device according to an embodiment;

FIG. 3 is a cross-sectional view of a substrate polishing device according to an embodiment, taken in a vertical direction;

FIG. 4 is a perspective view schematically illustrating a substrate cleaning device according to an embodiment; and

FIG. 5 is a flowchart illustrating a method of determining an abnormality occurrence in a substrate process system, according to an embodiment.

### DETAILED DESCRIPTION

Hereinafter, embodiments are described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. As used herein, the singular form is intended to include the plural forms as well, unless the context clearly indicates otherwise. It should be further understood that the terms "comprises/comprising" and/or "includes/including," when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical or scientific terms used herein have the same meaning as those commonly understood by one of ordinary skill in the art to which the embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing the embodiments with reference to the accompanying drawings, like reference numerals refer to like components and a repeated description related thereto is omitted. In the description of embodiments, detailed description of well-known related structures or functions is omitted when it is deemed that such description may cause ambiguous interpretation of the present disclosure.

In addition, in the description of the components of the embodiments, terms such as first, second, A, B, (a), (b), and the like may be used. These terms are used only for the purpose of discriminating one component from another component, and the nature, the sequences, the orders, or the like of the components are not limited by the terms. It is to be understood that when a component is described as being "connected," "coupled," or "joined" to another component, the former may be directly "connected," "coupled," or "joined" to the latter or "connected," "coupled," or "joined" to the latter via another component.

The same name may be used to describe components having the same function, which are included in different embodiments. Unless otherwise mentioned, the description of one embodiment may be applicable to another embodiment. Thus, duplicated description is omitted for conciseness.

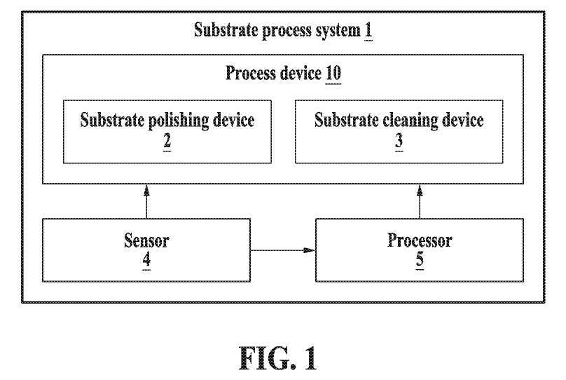

FIG. 1 is a block diagram schematically illustrating a substrate process system according to an embodiment.

Referring to FIG. 1, a substrate process system 1 according to an embodiment may be a system for performing a process on a substrate. For example, the process on a substrate may include a polishing process and/or a cleaning process. However, this is only an example, and the process that the substrate process system 1 may perform on a substrate is not limited thereto. For example, the substrate process system 1 may perform at least one of an oxidation process, a photolithography process, an etching process, a deposition process, or a metal wiring process.

In an embodiment, a substrate may be a silicon wafer for semiconductor manufacturing. However, the type of substrate is not limited thereto. For example, the substrate may include glass for a flat panel display device (FPD) such as a liquid crystal display (LCD) or a plasma display panel (PDP).

In an embodiment, the substrate process system 1 may include a process device 10, a sensor 4, and a processor 5. The process device 10 may be configured to perform the process on a substrate. For example, the process device 10 may include a substrate polishing device 2 and a substrate cleaning device 3. However, this is only an example, and the type of the process device 10 is not limited thereto.

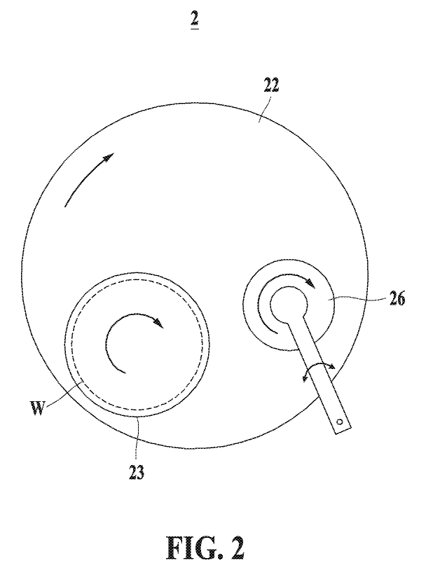

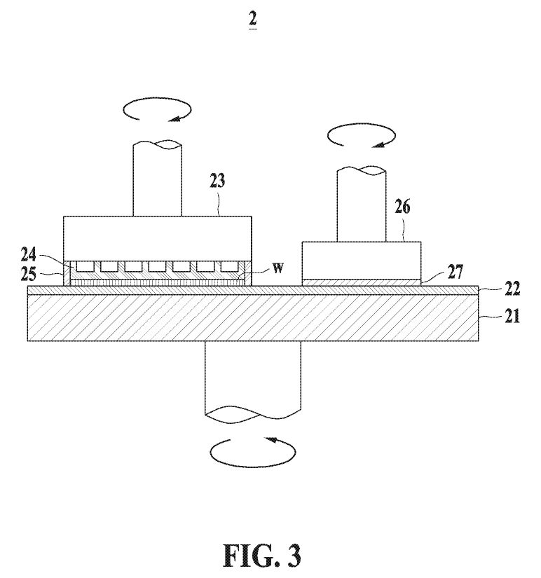

FIG. 2 is a plan view of a substrate polishing device according to an embodiment. FIG. 3 is a cross-sectional view of a substrate polishing device according to an embodiment, taken in a vertical direction.

Referring to FIGS. 2 and 3, the substrate polishing device 2 according to an embodiment may be a device for polishing a substrate. For example, the substrate polishing device 2 may perform a chemical mechanical polishing (CMP) process on the substrate.

In an embodiment, the substrate polishing device 2 may include a platen 21, a polishing pad 22, a carrier head 23, a membrane 24, a retainer ring 25, a conditioner 26, and a conditioning disc 27. However, this is only an example, and components of the substrate polishing device 2 are not limited thereto.

In an embodiment, the platen 21 may rotate about a rotation axis. The polishing pad 22 may be positioned on the platen 21. The polishing pad 22 may be a component to polish a substrate W by contacting the substrate W.

In an embodiment, the carrier head 23 may be positioned above the polishing pad 22. The carrier head 23 may rotate about a rotation axis. The carrier head 23 may be movable in a horizontal direction and/or a vertical direction. The membrane 24 and the retainer ring 25 may be connected to a lower portion of the carrier head 23. The membrane 24 may be a component to grip the substrate W. The membrane 24 may be formed of an elastically deformable material. The membrane 24 may include a plurality of chambers for controlling a pressing force. The retainer ring 25 may be connected to the lower portion of the carrier head 23 to surround the membrane 24 from an outer side of the membrane 24. The retainer ring 25 may surround the substrate W, gripped by the membrane 24, from an outer side of the substrate W. The retainer ring 25 may prevent the substrate W from being separated from a gripped position. For example, the retainer ring 25 may support a side surface of the substrate W so that the substrate W may not be separated from the carrier head 23 due to vibration and/or friction generated during a polishing process.

In an embodiment, the conditioner 26 may be a component to maintain a state of a surface of the polishing pad 22. The conditioner 26 may be positioned above the polishing pad 22. The conditioner 26 may rotate about a rotation axis. The conditioner 26 may pivot about a pivot axis by a swing arm. The conditioning disc 27 may be connected to a lower portion of the conditioner 26. The conditioning disc 27 may be in contact with the surface of the polishing pad 22 to finely cut the surface of the polishing pad 22 so that foam micro-pores formed on the surface of the polishing pad 22 may not be clogged.

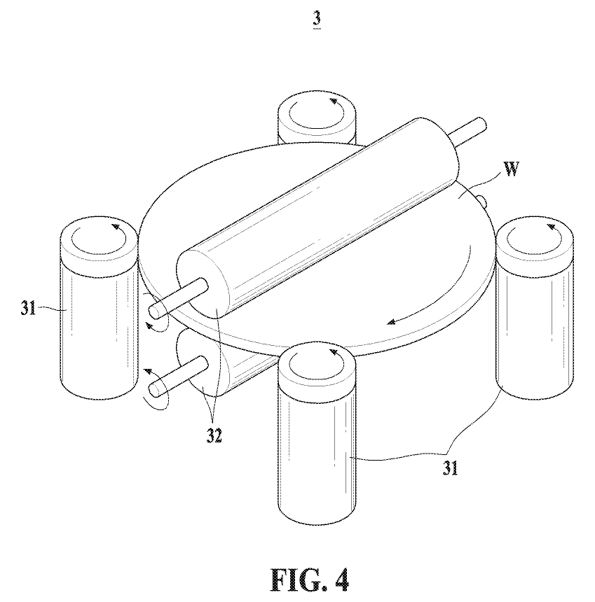

FIG. 4 is a perspective view schematically illustrating a substrate cleaning device according to an embodiment.

Referring to FIG. 4, the substrate cleaning device 3 may be a device for cleaning a substrate. For example, the substrate cleaning device 3 may be a device for cleaning a substrate polished by the substrate polishing device 2.

In an embodiment, the substrate cleaning device 3 may include a spindle 31 and a cleaning brush 32. For example, the substrate cleaning device 3 may clean the substrate in a contact manner using the cleaning brush 32.

In an embodiment, the spindle 31 may be a component to grip the substrate W and rotate the substrate W. For example, the spindle 31 may rotate while supporting an edge of the substrate W. The cleaning brush 32 may rotate while in contact with the substrate W to clean the substrate W. For example, the cleaning brush 32 may rotate about a rotation axis parallel to a surface of the substrate W. For example, the cleaning brush 32 may be formed in a cylindrical shape. Fine protrusions may be formed on a surface of the cleaning brush 32. The cleaning brush 32 may be provided in a pair to clean each of a front surface and a rear surface of the substrate W.

However, this is only an example, and the type and/or components of the substrate cleaning device 3 are not limited thereto. For example, the substrate cleaning device 3 may clean the substrate W in a non-contact manner.

Referring to FIGS. 1 to 4, according to an embodiment, the sensor 4 may be configured to detect driving noise generated from the process device 10. The driving noise may be understood to include all kinds of noise generated while operating the process device 10. For example, the driving noise may include noise generated from an actuator for operating the process device 10, noise generated by friction between each member, and/or noise generated by supplying a substance such as a chemical liquid. However, this is only an example, and the type of driving noise is not limited thereto. The sensor 4 may include an acoustic sensor and/or a microphone for detecting sound.

In an embodiment, the processor 5 may be a component for controlling the substrate process system 1. The processor 5 may be configured to control an operation of the process device 10. For example, the processor 5 may include memory and/or a central processing unit (CPU) to execute a stored program.

In an embodiment, the processor 5 may be configured to analyze the driving noise detected by the sensor 4 and determine an abnormality occurrence in the process device 10. For example, driving noise generated when the process device 10 is in a normal state may be different from driving noise generated when the process device 10 is in an abnormal state. The processor 5 may be configured to detect the difference and determine an abnormality occurrence in the process device 10. For example, the processor 5 may be configured to determine what kind of abnormality has occurred in which component of the process device 10.

In an embodiment, the processor 5 may be configured to determine an abnormality occurrence in the process device 10 using a database storing information regarding driving noise in a normal state and/or in each abnormal state. Information regarding driving noise that has actually been generated when the drive device 10 was in a normal state and/or information regarding driving noise that has actually been generated when the drive device 10 was in each abnormal state may be stored in the database in advance. For example, the database may store information regarding driving noise in a normal state and/or in various abnormal states for each component and/or each device. The processor 5 may compare the driving noise detected by the sensor 4 with the driving noise in each abnormal state and/or in a normal state stored in the database. When it is determined that the driving noise detected by the sensor 4 matches the driving noise in a normal state stored in the database, the processor 5 may determine that the process device 10 may currently be in a normal state. When it is determined that the driving noise detected by the sensor 4 matches the driving noise in an abnormal state stored in the database, the processor 5 may determine that the process device 10 may currently be in the corresponding abnormal state.

In an embodiment, when the processor 5 compares the driving noise detected by the sensor 4 with the driving noise stored in the database, various methods may be used, such as a Fourier transform, a short time Fourier transform (STFT), a Wavelet transform, envelope analysis, machine learning, and/or pattern analysis. However, these are only examples, and the method of comparing and analyzing driving noise is not limited thereto.

In an embodiment, the processor 5 may be configured to convert the driving noise into a frequency domain through a Fourier transform and detect a change in a frequency spectrum. For example, the processor 5 may compare a frequency spectrum in a normal state and/or in an abnormal state, stored in the database, with a frequency spectrum of the driving noise detected by the sensor 4. For example, the processor 5 may compare and analyze shapes of the frequency spectrums or compare and analyze an increase or decrease in an amplitude of a specific frequency band. For example, in a particular abnormal state, the amplitude of a specific frequency band may significantly increase or decrease. The processor 5 may detect this feature and determine whether the process device 10 is in an abnormal state. For example, information regarding a specific frequency band detected in association with the driving noise in each abnormal state and information regarding an amplitude of the corresponding frequency band may be stored in the database in advance. For example, when it is determined that a specific frequency band in a detected frequency spectrum has an amplitude greater than or equal to, or less than or equal to, a predetermined amplitude, the processor 5 may determine that the process device 10 may be in the corresponding abnormal state.

In an embodiment, the processor 5 may analyze the driving noise through STFT. For example, the processor 5 may be configured to convert the driving noise into a time-frequency domain through a Fourier transform for each determined time interval and detect a change in a time-frequency spectrum. The time interval may be set discretely or set to overlap each other. Alternatively, the processor 5 may be configured to convert the driving noise into a time-frequency domain through a Wavelet transform and detect a change in a time-frequency spectrum. For example, the driving noise may be converted into a time-frequency domain using Morlet wavelet, Daubechies wavelet, Coiflet wavelet, biorthogonal wavelet, Mexican hat wavelet, and/or symlet wavelet. Through the STFT or wavelet transform, a change in frequency or amplitude over time may be identified. For example, the processor 5 may compare a time-frequency spectrum in a normal state and/or in an abnormal state, stored in the database, with a time-frequency spectrum of the driving noise detected by the sensor 4. For example, the processor 5 may compare and analyze shapes of the time-frequency spectrums or compare and analyze an increase or decrease in an amplitude of a specific time and/or a specific frequency band. For example, in a particular abnormal state, the amplitude of a specific time and/or a specific frequency band may significantly increase or decrease. The processor 5 may detect this feature and determine whether the process device 10 is in an abnormal state. For example, information regarding a specific time and/or a specific frequency band detected in association with the driving noise in each abnormal state and information regarding an amplitude of the corresponding time and/or the corresponding frequency band may be stored in the database in advance. For example, when it is determined that a specific time and/or specific frequency band in a detected time-frequency spectrum has an amplitude greater than or equal to, or less than or equal to, a predetermined amplitude, the processor 5 may determine that the process device 10 may be in the corresponding abnormal state.

In an embodiment, the processor 5 may be configured to determine an abnormality occurrence in the process device 10 through Envelope analysis, which tracks a change in an amplitude of a designated target frequency band for the driving noise. For example, information regarding a target frequency band for each component of each process device 10 may be stored in the database. For example, information regarding a specific frequency band detected in association with the driving noise in each abnormal state and information regarding an amplitude of the corresponding frequency band may be stored, for each process device 10, in the database in advance. The processor 5 may track a change in an amplitude of each target frequency band, for each target frequency band stored in the database, from the detected driving noise. The processor 5 may determine whether the amplitude of the target frequency band of the detected driving noise corresponds to the information regarding the amplitude stored in the database to determine whether the process device 10 is in the corresponding abnormal state.

In an embodiment, the processor 5 may learn a pattern of the driving noise generated in a normal state and/or in each abnormal state through machine learning. For example, the processor 5 may learn a pattern in a time domain, a frequency domain, and/or a time-frequency domain. The pattern of the driving noise may be a concept including a wavelength, an amplitude, a gradient, an inflection point, and/or a waveform. For example, machine learning may be performed through supervised learning, unsupervised learning, and/or reinforcement learning. A pattern learned may be stored in the database. The processor 5 may extract a pattern from the driving noise detected by the sensor 4. The processor 5 may be configured to compare and analyze the extracted pattern with the learned pattern of each state to determine an abnormality occurrence of the process device 10. For example, the processor 5 may analyze a match rate between the extracted pattern and the learned pattern stored in the database. For example, when the match rate between the extracted pattern and a specific learned pattern is greater than or equal to a specified value, the processor 5 may determine that the process device 10 may be in the corresponding abnormal state.

In an embodiment, the processor 5 may perform preprocessing before analyzing the driving noise. For example, the processor 5 may perform preprocessing for removing noise from the driving noise detected by the sensor 4. For example, the processor 5 may use a filter (e.g., a high-pass filter, a low-pass filter, and/or a bandpass filter) for removing external noise. However, this is only an example, and a method for preprocessing is not limited thereto. For example, an algorithm for external noise removal may be learned through machine learning.

In an embodiment, a consumable member used in the process device 10 may partially wear out as a process progresses. The consumable member may refer to a member which requires replacing as at least a portion thereof wears out as a process progresses. For example, the consumable member may be a member that wears out due to friction while a process is in progress. The consumable member may be at least one of, for example, the polishing pad 22, the retainer ring 25, the conditioning disc 27, or the cleaning brush 32. As the consumable member wears out, the driving noise generated from the process device 10 may change. To respond to the change, the processor 5 may calibrate the driving noise detected by the sensor 4 based on a degree of wear of the consumable member. For example, a calibration algorithm may be preset through a prior experiment or learned through machine learning. Alternatively, the processor 5 may be configured to detect a change in the driving noise detected by the sensor 4 to determine the degree of wear of the consumable member.

In an embodiment, the processor 5 may generate a notification in a visual and/or auditory manner when it is determined that an abnormality has occurred in the process device 10. When it is determined that an abnormality has occurred in the process device 10, the processor 5 may automatically stop a process of the process device 10.

In an embodiment, the processor 5 may be configured to detect a premonitory pattern from the driving noise detected by the sensor 4 and generate a preemptive notification before the process device 10 enters an abnormal state. For example, in the process of the process device 10 transitioning from a normal state to an abnormal state, a specific premonitory pattern may be detected from the driving noise. The premonitory pattern of the driving noise may be understood as a kind of premonitory symptom that appears in the driving noise before the process device 10 enters an abnormal state. The premonitory pattern may be preset through a prior experiment or learned through machine learning. The processor 5 may detect whether the premonitory pattern appears in the driving noise detected by the sensor 4. The processor 5 may be configured to predict, when the premonitory pattern is detected, that the process device 10 may transition to an abnormal state and to generate a preemptive notification before the process device 10 enters an abnormal state.

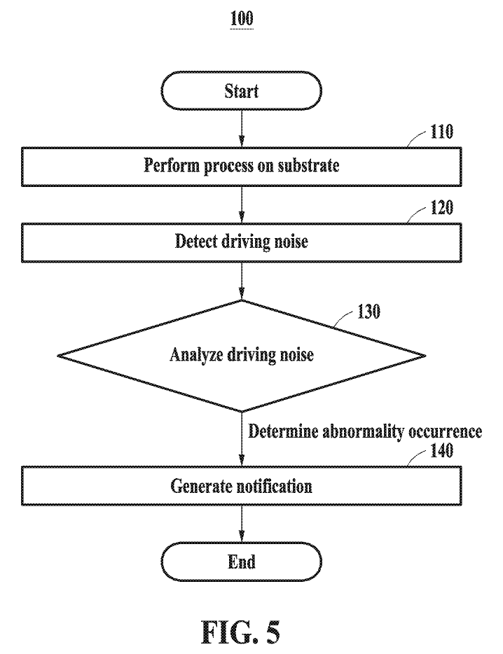

FIG. 5 is a flowchart illustrating a method of determining an abnormality occurrence in a substrate process system, according to an embodiment. However, FIG. 5 is only an example, and it will be clearly understood by one of ordinary skill in the art that some operations may be performed in parallel with other operations, the order of the operations may be changed, some operations may be omitted, or another operation may be added.

A method 100 of determining an abnormality occurrence in a substrate process system may be performed by the substrate process system 1 described with reference to FIGS. 1 to 4. Hereinafter, in the description of the method 100 of determining an abnormality occurrence in a substrate process system, the above description with reference to FIGS. 1 to 4 may be applied mutatis mutandis to any repeated content.

In an embodiment, the method 100 of determining an abnormality occurrence in a substrate process system may include operation 110 of performing a process on a substrate, operation 120 of detecting driving noise, operation 130 of analyzing the driving noise, and operation 140 of generating a notification.

In an embodiment, operation 110 may be an operation of performing a process on a substrate in a substrate process system. For example, the process on a substrate may include a polishing process and/or a cleaning process. However, the process on a substrate is not limited thereto. For example, the process on a substrate may include at least one of an oxidation process, a photolithography process, an etching process, a deposition process, or a metal wiring process.

In an embodiment, operation 120 may be an operation of detecting driving noise generated from a process device. Operation 120 may be performed by a sensor. For example, the driving noise may be understood to include all kinds of noise generated while operating the process device.

In an embodiment, operation 130 may be an operation in which a processor analyzes the driving noise detected by the sensor and determines an abnormality occurrence in the process device. For example, the processor may determine what kind of abnormality has occurred in which component of the process device through driving noise analysis. Operation 130 may be performed in real time. The driving noise analysis may be performed using a database storing information regarding driving noise in a normal state and/or in each abnormal state. For example, the database may store information regarding driving noise in a normal and/or in various abnormal states for each component and/or each device. The processor may compare the driving noise detected by the sensor with the driving noise in each abnormal state and/or in a normal state stored in the database. When it is determined that the driving noise detected by the sensor matches the driving noise in a normal state stored in the database, the processor may determine that the process device may currently be in a normal state. When it is determined that the driving noise detected by the sensor matches the driving noise in an abnormal state stored in the database, the processor may determine that the process device may currently be in the corresponding abnormal state. When the processor compares the driving noise detected by the sensor with the driving noise stored in the database, various methods may be used, such as a Fourier transform, an STFT, a Wavelet transform, envelope analysis, machine learning, and/or pattern analysis. However, these are only examples, and the method of comparing and analyzing driving noise is not limited thereto.

In an embodiment, operation 140 may be an operation in which the processor generates a notification when it is determined that an abnormality has occurred in the process device. For example, the processor may generate a notification in a visual and/or auditory manner. When it is determined that an abnormality has occurred in the process device, the processor may automatically stop a process of the process device.

In an embodiment, the method 100 of determining an abnormality occurrence in a substrate process system may further include an operation of generating a preemptive notification. The operation of generating a preemptive notification may be an operation of generating a notification for a user before the process device enters an abnormal state. For example, the processor may detect a premonitory pattern from the driving noise detected from the sensor. When the premonitory pattern is detected, the processor may predict that the process device may transition to an abnormal state, and may generate a preemptive notification before the process device enters an abnormal state. The operation of generating a preemptive notification may be performed prior to operation 140.

The methods according to the embodiments may be recorded in non-transitory computer-readable media including program instructions to implement various operations of the embodiments. The media may also include the program instructions, data files, data structures, and the like alone or in combination. The program instructions recorded on the media may be those specially designed and constructed for the purposes of embodiments, or they may be of the kind well-known and available to one of ordinary skill in the computer software arts. Examples of non-transitory computer-readable media include magnetic media such as hard disks, floppy disks, and magnetic tape; optical media such as compact disc read-only memory (CD-ROM) discs and digital video discs (DVDs); magneto-optical media such as floptical disks; and hardware devices that are specially configured to store and perform program instructions, such as read-only memory (ROM), random-access memory (RAM), flash memory, and the like. Examples of program instructions include both machine code, such as those produced by a compiler, and files containing high-level code that may be executed by the computer using an interpreter. The above-described hardware devices may be configured to act as one or more software modules in order to perform the operations of the embodiments, or vice versa.

The software may include a computer program, a piece of code, an instruction, or one or more combinations thereof, to independently or collectively instruct or configure the processing device to operate as desired. Software and/or data may be embodied permanently or temporarily in any type of machine, component, physical or virtual equipment, computer storage medium or device, or in a propagated signal wave for the purpose of being interpreted by the processing device or providing instructions or data to the processing device. The software may also be distributed over network-coupled computer systems so that the software is stored and executed in a distributed fashion. The software and data may be stored by one or more non-transitory computer-readable recording mediums.

While the embodiments are described with reference to a limited number of drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or substituted by other components or their equivalents.

Therefore, other implementations, other embodiments, and equivalents to the claims are also within the scope of the following claims.

What is claimed is:

1. A substrate process system comprising:
a process device configured to perform a process on a substrate;
a sensor configured to detect driving noise generated from the process device; and
a processor configured to analyze the driving noise detected by the sensor and determine an abnormality occurrence in the process device.

2. The substrate process system of claim 1, wherein the processor is configured to:
determine an abnormality occurrence in the process device using a database storing information regarding driving noise in a normal state and information regarding driving noise in each abnormal state.

3. The substrate process system of claim 1, wherein the processor is configured to:
convert the driving noise into a frequency domain through a Fourier transform and detect a change in a frequency spectrum.

4. The substrate process system of claim 3, wherein the processor is configured to:
convert the driving noise into a time-frequency domain through a Fourier transform for each determined time interval and detect a change in a time-frequency spectrum.

5. The substrate process system of claim 1, wherein the processor is configured to:
convert the driving noise into a time-frequency domain through a wavelet transform and detect a change in a time-frequency spectrum.

6. The substrate process system of claim 1, wherein the processor is configured to:
determine an abnormality occurrence in the process device through Envelope analysis, which tracks a change in an amplitude of a designated target frequency band for the driving noise.

7. The substrate process system of claim 1, wherein the processor is configured to:
learn a pattern of driving noise generated in a normal state and an abnormal state through machine learning and compare and analyze a pattern extracted from the driving noise detected by the sensor with a learned pattern of each state to determine an abnormality occurrence in the process device.

8. The substrate process system of claim 1, wherein the processor is configured to:
calibrate the driving noise detected by the sensor based on a degree of wear of a consumable member.

9. The substrate process system of claim 1, wherein the processor is configured to:
generate a notification when it is determined that an abnormality has occurred in the process device.

10. The substrate process system of claim 1, wherein the processor is configured to:
detect a premonitory pattern from the driving noise detected by the sensor and generate a notification in advance before the process device enters an abnormal state.

11. The substrate process system of claim 1, wherein the process device comprises:
a substrate polishing device or a substrate cleaning device.

12. A method of determining an abnormality occurrence in a process device using the substrate process system according to claim 1, the method comprising:
performing a process on the substrate;
detecting driving noise generated from the process device; and
analyzing, by the processor, the driving noise detected by the sensor and determining, by the processor, an abnormality occurrence in the process device.

13. The method of claim 12, further comprising:
generating, by the processor, a notification for a user when it is determined that an abnormality has occurred in the process device.
